(19) United States
(12) Patent Application Publication
(10) Pub. No.: US 2012/0317886 A1
(43) Pub. Date: Dec. 20, 2012

(54) COVER MODULE

(75) Inventors: Kuo-Chuan Liu, New Taipei City (TW); Chin-Lung Fan, New Taipei City (TW)

(73) Assignee: WISTRON CORP., New Taipei City (TW)

(21) Appl. No.: 13/458,958

(22) Filed: Apr. 27, 2012

(30) Foreign Application Priority Data
Jun. 15, 2011 (TW) TW100120836

(51) Int. Cl. H05K 7/00

(52) U.S. Cl. 49/465

(57) ABSTRACT

A cover module is provided, including a main body, a rotary nub, a cam connected to the rotary nub, and at least a slider. The rotary nub and the cam are pivotally disposed on a first side and a second side of the main body, respectively, wherein the second side is opposite to the first side. The slider is movably disposed on the second side of the main body. When the cam is driven by the rotary nub to rotate from a first angle to a second angle, the slider is pushed by the cam from a first position to a second position relative to the main body, such that the slider engages with a housing of an electronic device.

### CROSS REFERENCE TO RELATED APPLICATIONS

This Application claims priority of Taiwan Patent Application No. 100120836, filed on Jun. 15, 2011, the entirety of which is incorporated by reference herein.

### BACKGROUND OF THE INVENTION

1. Field of the Invention

This application relates in general to a cover module and in particular to a cover module detachably connected to a housing of an electronic device.

2. Description of the Related Art

Portable electronic devices such as notebook PCs may comprise a battery cover or rear cover. Generally, the battery cover or the rear cover can be detached from the electronic device when replacing batteries or other electrical components therein. Additionally, some conventional electronic devices may comprise a housing, a cover plate detachably disposed on the housing, and a plurality of rotary nubs, wherein the cover plate is provided corresponding to an opening of the housing. The rotary nubs are usually disposed on different sides of the openings and rotatable between a release position and a joining position. When the rotary nubs rotate to the joining position, the cover plate can be joined with the housing. However, as the cover plate is usually rectangular and forms a plurality of sides, the users must rotate the rotary nubs one by one to assemble the cover plate to the housing, and this may lead to inconvenience of usage.

### BRIEF SUMMARY OF INVENTION

An object of the application is to provide a cover module, including a main body, a rotary nub, a cam connected to the rotary nub, and at least a slider. The rotary nub is disposed on a first side of the main body and the cam is pivotally disposed on a second side of the main body, wherein the second side is opposite to the first side. The slider is movably disposed on the second side of the main body. When the cam is driven by the rotary nub to rotate from a first angle to a second angle, the slider is pushed by the cam from a first position to a second position relative to the main body, such that the slider engages with a housing of an electronic device.

### BRIEF DESCRIPTION OF DRAWINGS

The invention can be more fully understood by reading the subsequent detailed description and examples with references made to the accompanying drawings, wherein:

FIG. 1 is an exploded diagram showing a cover module and a housing of an electronic device according to an embodiment of the invention;

FIG. 2 is an exploded diagram of a cover module according to an embodiment of the invention;

FIG. 3A is a perspective diagram of a cover module connected to a housing according to an embodiment of the invention;

FIG. 3B is a perspective diagram of a cam in a first angle and a plurality of sliders in a first position according to an embodiment of the invention;

FIG. 3C is an enlarged view of the portion A in FIG. 3B;

FIG. 4A is a perspective diagram of a rotary nub rotating clockwise relative to a main body of a cover module according to an embodiment of the invention;

FIG. 4B is a perspective diagram showing a cam pushing a plurality of sliders to move outwardly according to an embodiment of the invention;

FIG. 4C is an enlarged view of the portion B in FIG. 4B; and

FIG. 5 is a perspective diagram showing a plurality of sliders of a cover module engaged with a housing according to an embodiment of the invention.

### DETAILED DESCRIPTION OF INVENTION

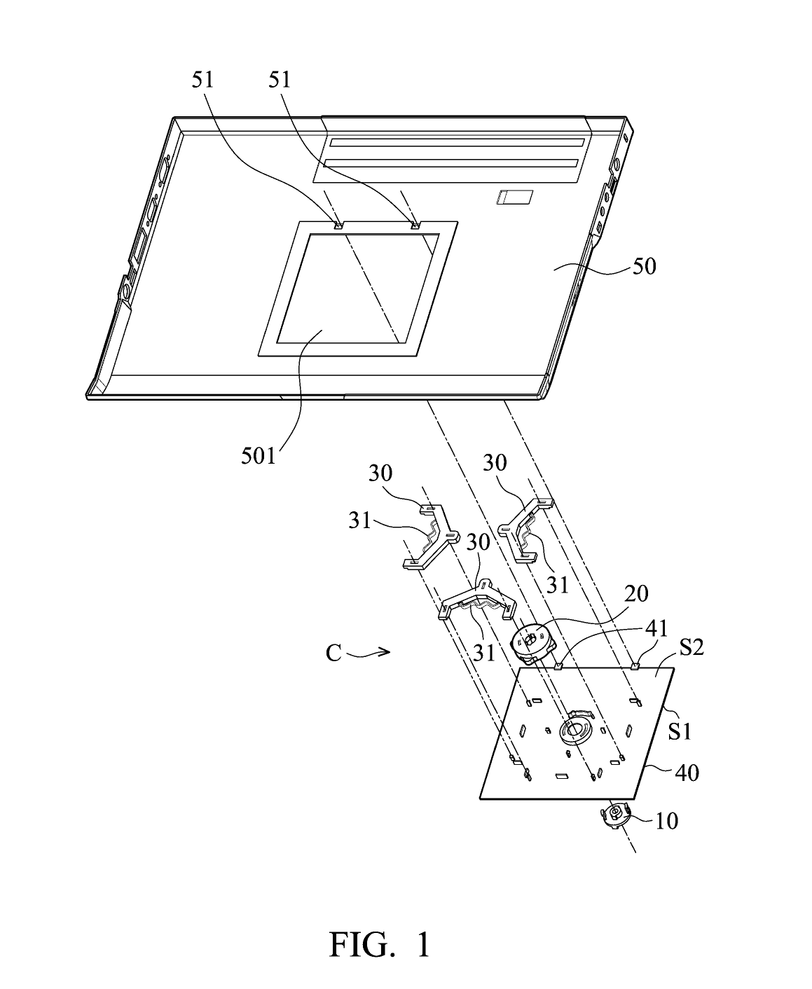

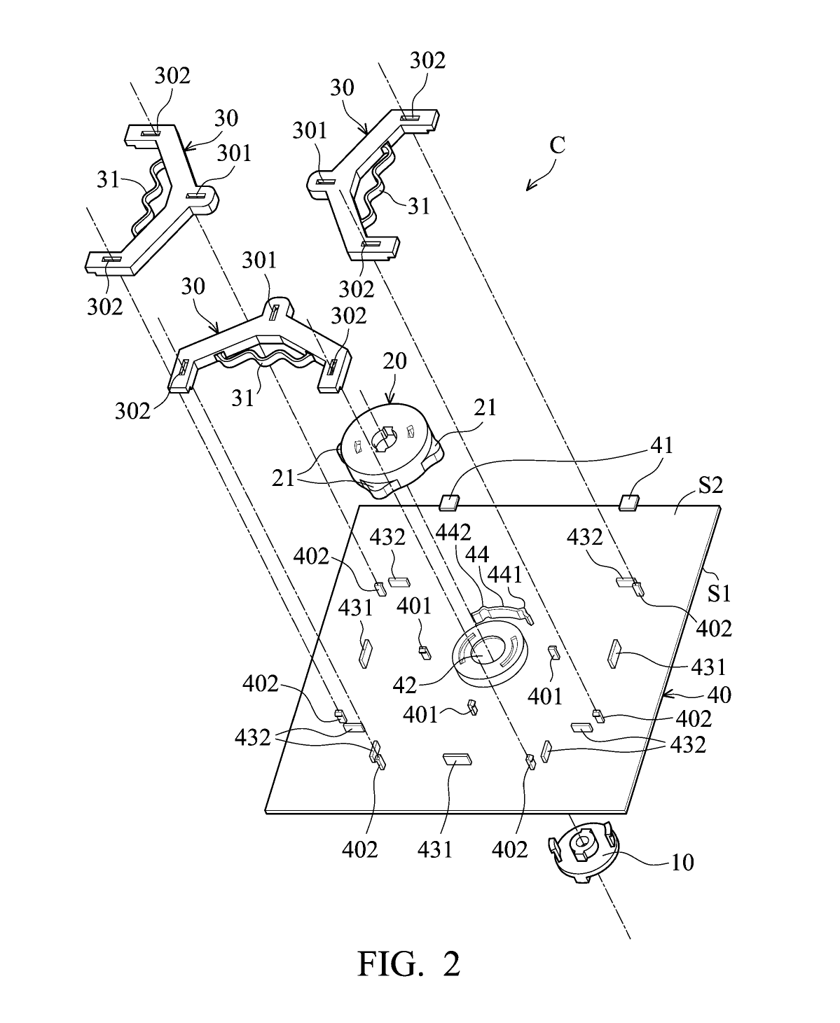

Referring to FIGS. 1 and 2, an embodiment of a cover module C may be used as a rear cover or a battery cover detachably connected to a housing 50 of an electronic device. The cover module C comprises a rotary nub 10, a cam 20, at least a slider 30, and a main body 40. When the cover module C is secured to the housing 50, an opening 501 on the housing 50 is blocked by the main body 40, so as to protect a battery or other electrical components in the electronic device.

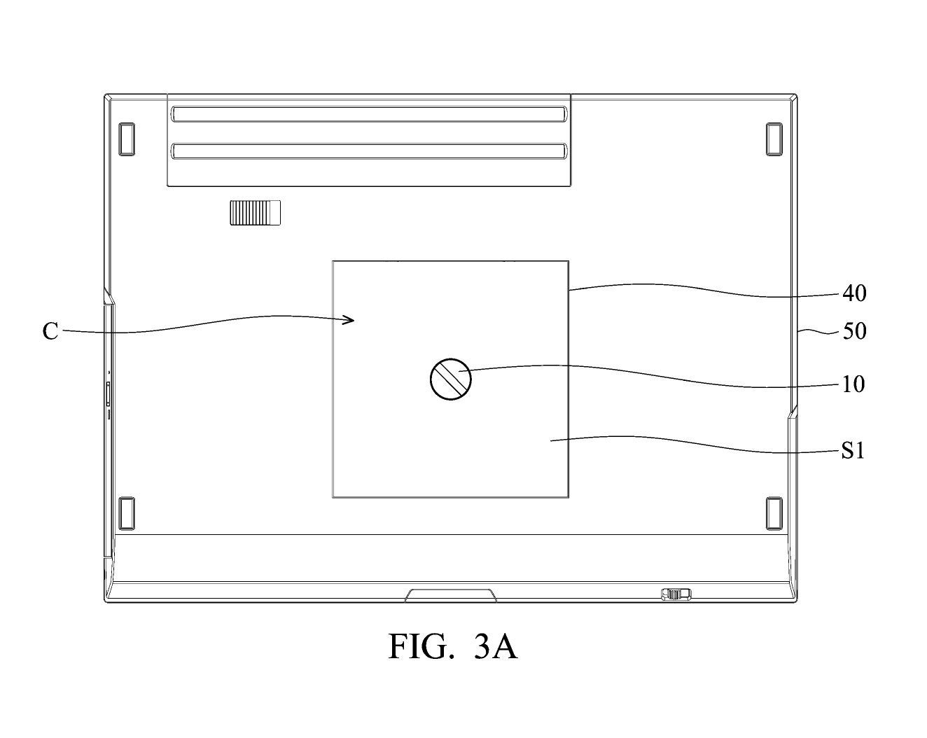

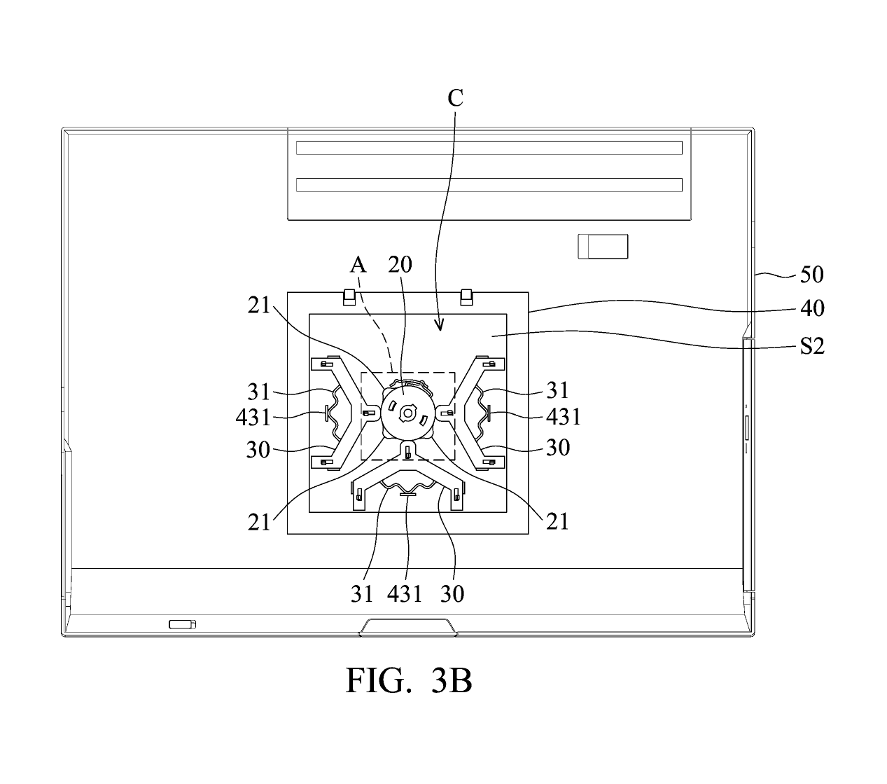

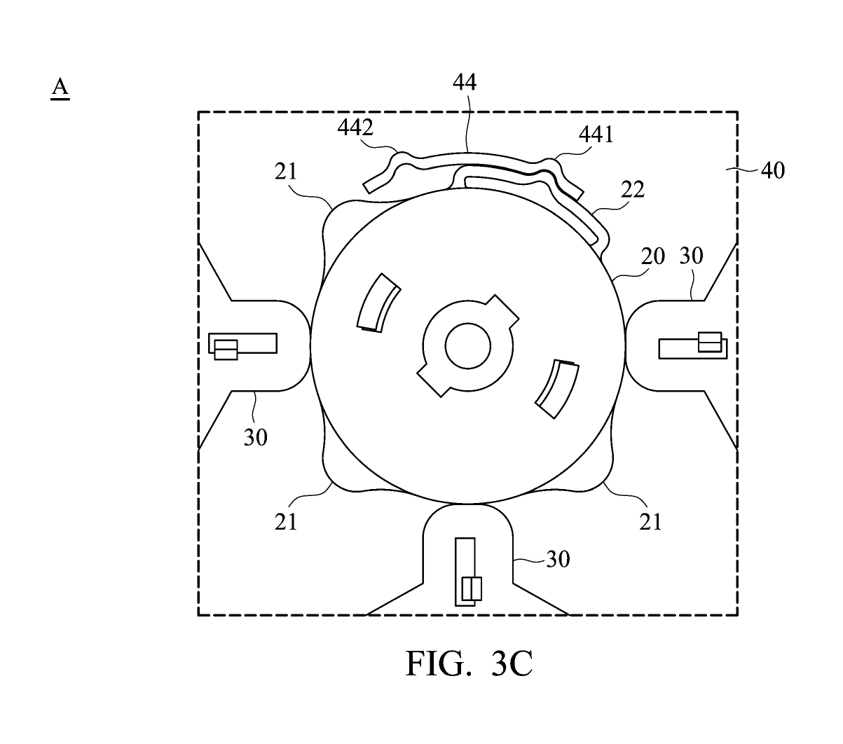

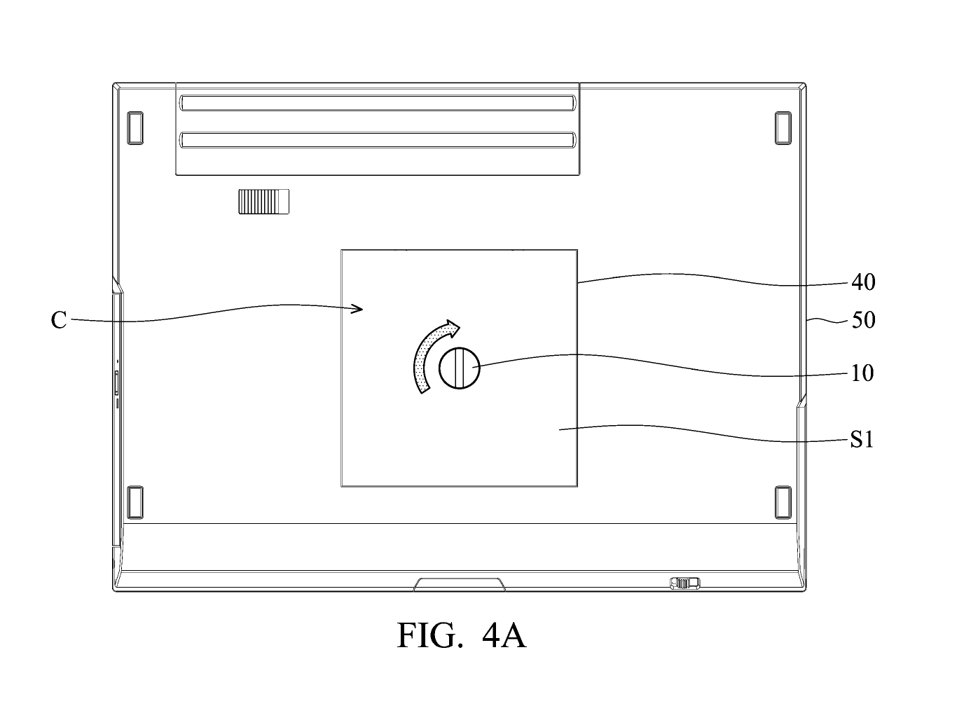

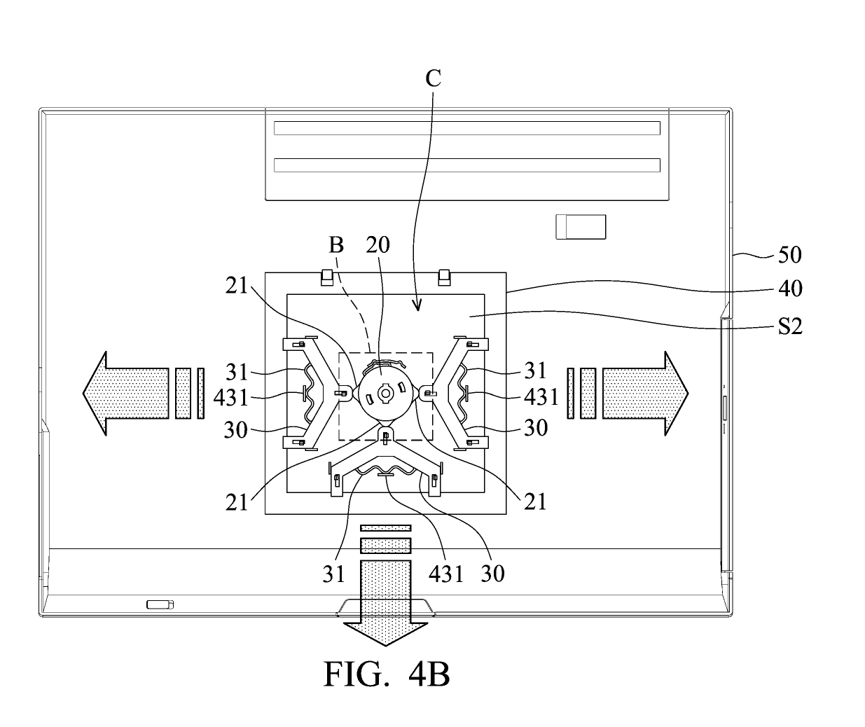

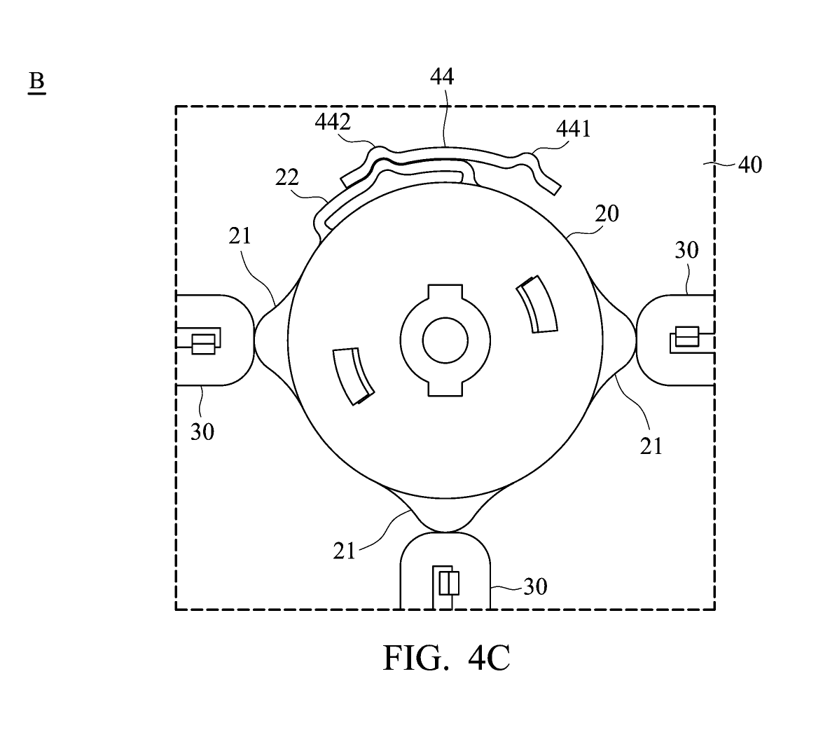

As depicted in FIGS. 1 and 2, the rotary nub 10 is rotatably disposed on a first side S1 of the main body 40, and the cam 20 is disposed on a second side S2 of the main body 40, opposite to the first side S1. The rotary nub 10 is extended through a hole 42 of the main body 40 and connected to the cam 20, wherein when the rotary nub 10 rotates relative to the main body 40, the cam 20 is rotated by the rotary nub 10. Furthermore, the sliders 30 are movably disposed on the second side S2 of the main body 40. When the cam 20 is impelled by the rotary nub 10 to rotate from a first angle (FIG. 3B) to a second angle (FIG. 4B), the sliders 30 are pushed outwardly with respect to the main body 40 by a protrusion 21 of the cam 20 from a first position (FIG. 3B) to a second position (FIG. 4B), such that the sliders 30 engage with the housing 50.

There are totally three sliders 30 provided in this embodiment, as shown in FIGS. 1 and 2, corresponding to three different sides of the rectangular main body 40. Moreover, the cam 20 may have three protrusions 21 corresponding to the three sliders 30. In this embodiment, the slider 30 is substantially Y-shaped and forms two symmetrical extending portions with a wave-shaped resilient member 31 disposed therebetween. When the cam 20 is in the first angle, the resilient member 31 can provide a resilient force to hold the slider 30 in the first position (FIG. 3B). In some embodiments, the resilient member 31 may comprise a spring or resilient sheet. In some embodiments, the slider 30 and the resilient member 31 may be plastic and integrally formed in one piece, thus saving production cost and facilitating easy assembly.

The main body 40 in FIG. 2 forms several contact portions 431, guiding portions 432, and projecting portions 401 and 402 on the second side S2 thereof. The resilient members 31 abut the contact portions 431, and the sliders 30 can slide relative to the main body 40 along the guiding portions 432. In this embodiment, each of the sliders 30 form two guiding channels 301 and 302, corresponding to the projecting portions 401 and 402. When the slider 30 moves relative to the main body 40, the projecting portions 401 and 402 slide along the guiding channels 301 and 302. As described above, the guiding portions 432 and the projecting portions 401 and 402 can guide the sliders 30 to move linearly relative to the main body 40, thus improving stability of the sliding mechanism and preventing separation of the sliders 30 from the main body 40 due to external impact.

Referring to FIGS. 1 and 3A-3B, when assembling the cover module C to the housing 50, the opening 501 (FIG. 1) on the housing 50 is blocked by the rectangular main body 40, and two hooks 41 of the main body 40 are respectively joined to two slots 51 of the housing 50 in advance. As the cam 20 has not been rotated by the rotary nub 10, the cam 20 remains in the first angle, and the sliders 30 are disengaged from the housing 50. In this circumstance, the resilient member 31 can provide a resilient force to hold the sliders 30 in the first position, as shown in FIG. 3B. Since the sliders 30 are not engaged with the housing 50, users can still detach the cover module C from the housing 50.

FIG. 3C is an enlarged view of the portion A in FIG. 3B. As shown in FIGS. 2 and 3C, the main body 40 forms a retaining portion 44 protruding from the second side S2 of the main body 40, wherein the retaining portion 44 forms a first recess 441 and a second recess 442. When the cam 20 is in the first angle, a positioning portion 22 of the cam 20 is engaged in the first recess 441, so as to restrict the cam 20 in the first angle.

Referring to FIGS. 4A and 4B, when the user rotates the rotary nub 10 on the first side S1 of the main body 40 (as the arrow indicates in FIG. 4A), the cam 20 on the second side S2 of the main body 40 is rotated by the rotary nub 10 from the first angle to a second angle. Thus, the sliders 30 are pushed by the protrusions 21 of the cam 20 and slide outwardly with respect to the main body 40 from the first position to the second position, such that the cover module C is secured to the housing 50.

FIG. 4C is an enlarged view of the portion B in FIG. 4B. As shown in FIG. 4C, when the cam 20 is rotated by the rotary nub 10 from the first angle to the second angle, the positioning portion 22 of the cam 20 is engaged in the second recess 442 of the retaining portion 44, so as to restrict the cam 20 in the second angle.

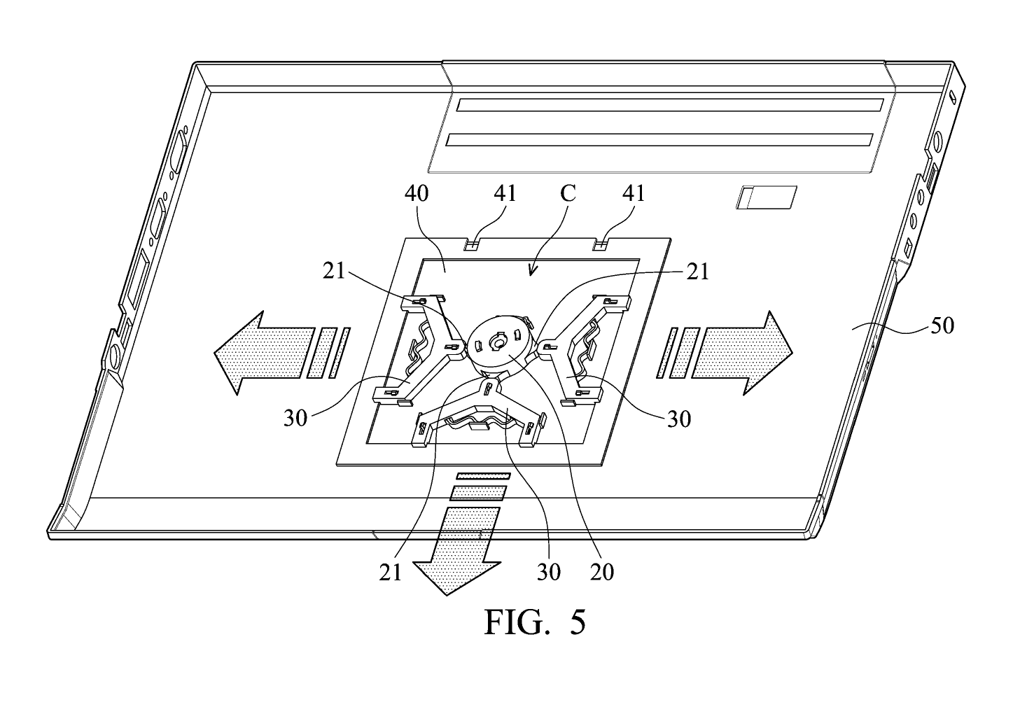

As the arrows indicate in FIG. 5, the sliders 30 are engaged with the housing 50 when sliding outwardly with respect to the main body 40 to the second position. Moreover, the rotary nub 10 can also be rotated in an opposite direction to disengage the sliders 30 from the housing 50, wherein the protrusions 21 of the cam 20 are released from the sliders 30. Thus, the sliders 30 are returned to the first position by the resilient force of the resilient members 31, as shown in FIG. 3B, such that the cover module C can be detached from the housing 50.

The invention provides a cover module, such as a rear cover or a battery cover of an electronic device, to protect a battery or other electrical components in the electronic device. The cover module primarily comprises a rotary nub, at least a cam, at least a slider, and a main body. When a user rotates the rotary nub, the cam is rotated by the rotary nub and pushes the slider to move outwardly with respect to the main body, so as to engage the cover module with a housing of the electronic device. Since the cover module has a simple mechanism and is easy to assemble, it can be widely applied in notebook PCs or other electronic devices.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A cover module, detachably connected to a housing of an electronic device, comprising:
a main body, having a first side and a second side opposite to the first side;
a rotary nub, rotatably disposed on the first side of the main body;
a cam, rotatably disposed on the second side of the main body and connected to the rotary nub, wherein the cam has at least a protrusion; and
at least a slider, movably disposed on the second side of the main body, wherein when the cam is impelled by the rotary nub to rotate from a first angle to a second angle, the slider is pushed by the protrusion of the cam from a first position to a second position relative to the main body, such that the slider engages with the housing of the electronic device.

2. The cover module as claimed in claim 1, wherein the cover module further comprises a resilient member disposed between the main body and the slider, and the resilient member provides a resilient force to hold the slider in the first position.

3. The cover module as claimed in claim 2, wherein the resilient member and the slider are integrally formed in one piece.

4. The cover module as claimed in claim 2, wherein the resilient member and the slider comprise plastic.

5. The cover module as claimed in claim 2, wherein the resilient member comprises a spring or resilient sheet.

6. The cover module as claimed in claim 2, wherein the resilient member forms a wave-shaped structure.

7. The cover module as claimed in claim 2, wherein the main body further comprises a contact portion protruding from the second side and abutting the resilient member.

8. The cover module as claimed in claim 2, wherein the slider is Y-shaped and forms two symmetrical extending portions with the resilient member disposed therebetween.

9. The cover module as claimed in claim 1, wherein the main body further comprises a retaining portion protruding from the second side and forming a first recess and a second recess, and the cam further has a positioning portion moving from the first recess to the second recess when the cam rotates from the first angle to the second angle.

10. The cover module as claimed in claim 1, wherein the main body is substantially rectangular, the cover module further comprises three sliders corresponding to three different sides of the main body, and the cam further has three protrusions corresponding to the sliders.

11. The cover module as claimed in claim 1, wherein the housing has a slot, and the main body further has a hook joined in the slot.

12. The cover module as claimed in claim 1, wherein when the slider slides outwardly with respect to the main body from the first position to the second position, the cover module is engaged with the housing.

13. The cover module as claimed in claim 1, wherein the slider has a guiding channel, and the main body further has a projecting portion sliding along the guiding channel when the slider moves relative to the main body.

14. The cover module as claimed in claim 1, wherein the main body further has a guiding portion protruding from the second side, and the slider slides relative to the main body along the guiding portion.
